(19) United States
(12) Patent Application Publication
(10) Pub. No.: US 2009/0305146 A1
(43) Pub. Date: Dec. 10, 2009

(54) Optical recording medium and method for manufacturing the same

(75) Inventors: Naoki HAYASHIDA, Tokyo (JP); Atsuko KOSUDA, Tokyo (JP); Motohiro INOUE, Tokyo (JP); Jiro YOSHINARI, Tokyo (JP)

Correspondence Address: OLIFF & BERRIDGE, PLC, P.O. BOX 320850, ALEXANDRIA, VA, 22320-4850, US

(73) Assignee: TDK CORPORATION, TOKYO (JP)

(21) Appl. No.: 12/457,094

(22) Filed: Jun. 1, 2009

(30) Foreign Application Priority Data
Jun. 5, 2008 (JP) 2008-148005

(51) Int. Cl. G03F 7/004

(52) U.S. Cl. 430/2

(57) ABSTRACT

An optical recording medium includes a support substrate and an information recording layer which is supported on the support substrate and made of a photosensitive material which is irradiated with light to be refractive index modulated and amplitude modulated, thereby recording information. The information recording layer has the shape of a coating which is formed by applying a photosensitive material reversibly dissolved or dispersed in an organic solvent onto the support substrate. The photosensitive material in the shape of a coating, as a photopolymer for hologram recording material, contains the cross-linked matrix to maintain the rigidity of the recording material. The optical recording medium is retained in shape with stability, and particularly prevented from being deformed due to shrinkage, thereby facilitating manufacturing of the optical recording medium.

### BACKGROUND OF THE INVENTION

1. Field of the Invention

The present invention relates to an optical recording medium capable of recording holograms and a method for manufacturing the same.

2. Description of the Related Art

Japanese Translation of PCT International Application No. 2002-502057 discloses a device which enables successive mark-position recording or mark-edge recording of bit information on each local denatured region formed in format hologram layers of a holography storage medium. The local denatured region is selectively formed by focusing a high-power laser beam on a desired storage position in the format hologram layers formed at multiple depths in a recording layer of the medium.

With such a hologram recording medium, it is necessary to assure a sufficient increase in temperature in each of the format hologram layers through absorption of light as well as a sufficient amount of light reaching the lowermost layer. To this end, recording layers of a few μm to a few tens of μm in thickness may be deposited via a non-photosensitive transparent spacer layer, so that one reflective hologram can be formed in each recording layer.

On the other hand, for volume holographic storage, a page of data made up of multiple pieces of bit information is collectively recorded. In this case, a recording method has been suggested for stacking a plurality of volume holograms in the direction of depth (see Japanese Patent Application Laid-Open No. 2005-322382.) To provide servo stability during reproduction or to reduce crosstalk noise, each recording layer can be effectively separated from each other using a transparent spacer layer or translucent film.

To manufacture the aforementioned multilayer structure with stability and efficiency, recording material compositions having flowability may be applied to or deposited on a support substrate by spin coating or screen printing.

For example, Japanese Patent No. 3737306, WO 2005/78531, WO 2005/78532, and Japanese Patent Application Laid-Open No. 2008-70464 and No. 2008-76674 disclose a recording film structure. This recording film is made of a hologram recording material (photopolymer) which is prepared by mixing a low molecular-weight compound or a precursor of three-dimensional, cross-linked matrix and a polymerizable monomer, filling the mixture in between two support substrates, and cross-linking the precursor of three-dimensional, cross-linked matrix using an appropriate catalyst to form chemical bonds. This allows for providing a recording film such that a photopolymerizable monomer dispersed in the resulting three-dimensional, cross-linked matrix that has a practically sufficient strength.

Examples of known three-dimensional, cross-linked matrices for use in such a photopolymer may include polyurethane obtained through polymerization of an isocyanate and an alcohol in the presence of an accelerator (which is a tin compound or an amine compound), a polymer obtained through step-growth polymerization of an epoxy and a mercaptan in the presence of an amine catalyst, and the like.

However, these three-dimensional, cross-linked matrices exploit not thermally latent polymerization (initiated by heating) but a reaction of a type that causes polymerization to start at room temperatures immediately after the catalyst has been added. It is thus very difficult to successively apply them onto a support substrate such as by spin coating or screen printing.

This is because the final composition solution with the catalyst having been added thereto gradually polymerizes even at room temperatures, thereby preventing the solution from being successively supplied through a spin coating nozzle or a screen printing mask.

On the other hand, Japanese Patent Laid-Open Application No. 2008-76674 discloses a photopolymer which utilizes no chemical bonding in forming a three-dimensional, cross-linked structure. The three-dimensional structure matrix is formed not by chemical bonding but by ionic bonding or by formation of microcrystals as follows. That is, an ionomer resin or a resin having a crystal structure is employed to be mixed with a photopolymerizable monomer. Then, the mixture is filled evenly in between the substrates by hot pressing, and cooled down to room temperature to form ionic bonding or microcrystals. It is also claimed to be capable of avoiding shrinkage due to polymerization or the complexity of the manufacturing steps of media, which were conventionally problematic in cross-link formation by chemical bonding.

In the method disclosed in Japanese Patent Application Laid-Open No. 2008-76674, cross-links are formed not by chemical bonding, but the cross-link formation inevitably causes changes in size of the recording film. The change in size appears as shrinkage due to changes in temperature when the resin is cooled down to room temperature after hot pressing.

In other words, regardless of whether the cross-link is formed by chemical bonding, the shrinkage during the hardening process cannot be avoided so long as the recording material precursor is sealed in between the upper and lower support substrates before the hardening.

The aforementioned shrinkage of the recording film resulting from the hardening causes an uneven stress to remain inside the recording film, appearing as variations in recording characteristics across the recording layer surface.

The present inventors checked the method disclosed in Japanese Patent Application Laid-Open No. 2008-76674, with the result that it was very difficult to obtain stable recording characteristics across the entire surface of the optical recording medium.

Furthermore, when a material for forming a cross-linked structure through the formation of microcrystal is employed in the structure as disclosed in Japanese Patent Application Laid-Open No. 2008-76674, an increase in light scattering caused by the structure of the microcrystal cannot be generally avoided. But, this publication states that no problem was found in recording and reproduction using a laser beam of a wavelength of 523 nm.

However, light scattering becomes increasingly more detrimental as the wavelength of read/write beams become shorter. Thus, light scattering is expected to have more effects, for example, when the material disclosed in WO2005/78532 is employed in a read/write system that is designed for the blue laser beam (405 nm in wavelength).

In addition, in the example disclosed in Japanese Patent Application Laid-Open No. 2008-76674, a polymer material with a softening point lower than 70° C. is used as the matrix. Thus, at points higher than this temperature, recorded signals would not be retained with stability and could gradually disappear. In general, current optical recording media such as DVDs or Blu-ray (trademark) discs are required to retain recorded signals even at around 80° C.

### SUMMARY OF THE INVENTION

In view of the foregoing problems, various exemplary embodiments of this invention provide an optical recording medium which facilitates manufacturing of an information recording layer without its shrinkage and has stable recording characteristics. Further provided is a method for manufacturing the same.

As a result of intensive studies, the present inventors found that a composition (being gel or solid at room temperatures) for which a pre-reaction for forming a matrix has already completed can be dissolved and then applied to a support substrate, thereby manufacturing a multilayer structure with stability.

It was also found that in a temperature range of from room temperature to approximately 80° C., using a recording material including a matrix with a certain rigidity allows for maintaining recorded patterned holograms unchanged with stability for a long period of time.

Furthermore, for multiple information recording layers, the prospective number of stacked layers from which an effective increase in recording capacity can be expected should be balanced with the aberration tolerance of a read/write optical system. From this, it was also found that about 10 to 50 information recording layers, each 1 μm to 20 μm in thickness, were best stacked via a transparent spacer layer having a thickness of 1 μm to 20 μm.

In summary, the above-described objectives are achieved by the following embodiments of the present invention.

(1) An optical recording medium comprising: a support substrate; and an information recording layer supported on the support substrate and made of a photosensitive material capable of recording a hologram when being irradiated with light, wherein the information recording layer has a shape of a coating which is formed by applying the photosensitive material that is reversibly dissolved or dispersed in an organic solvent onto the support substrate.

(2) The optical recording medium according to (1), wherein the information recording layer is stacked in multiple layers via an isolation layer, and the isolation layer is insensitive to light of a recording/reproduction wavelength and has an extinction coefficient lower than that of the information recording layer.

(3) A method for manufacturing an optical recording medium, the optical recording medium having a support substrate and an information recording layer supported on the support substrate and made of a photosensitive material capable of recording a hologram when being irradiated with light, the method comprising: applying the photosensitive material that is reversibly dissolved or dispersed in an organic solvent onto the support substrate; and volatilizing at least part of the organic solvent to form the information recording layer having a shape of a coating.

(4) The method for manufacturing an optical recording medium according to (3), wherein the step of applying the photosensitive material is performed while maintaining the photosensitive material together with the organic solvent at a temperature from 40° C. to 100° C.

### BRIEF DESCRIPTION OF THE DRAWINGS

FIG. 1 is a schematic cross-sectional view illustrating an optical recording medium according to an example of the present invention;

FIG. 2 is a flowchart showing an example of a manufacturing process of the optical recording medium;

FIG. 3 is a schematic block diagram illustrating a hologram recording optical system which is used to evaluate a hologram recording medium according to an example and a comparative example of the present invention; and

FIG. 4 is a schematic diagram illustrating a manufacturing process of an optical recording medium according to an example of the present invention.

### DETAILED DESCRIPTION OF THE PREFERRED EMBODIMENTS

An optical recording medium according to a best mode includes a support substrate and an information recording layer supported on the support substrate. The information recording layer is made of a photosensitive material which is irradiated with light to be refractive index modulated and amplitude modulated, thereby recording information. The information recording layer has the shape of a coating which is formed by applying a photosensitive material reversibly dissolved or dispersed in an organic solvent onto the support substrate.

As used herein, the phrase “reversibly dissolved or dispersed in an organic solvent” means that an already optically recordable photosensitive material can provide the same optical recording characteristics between before and after the material is dissolved or dispersed in an organic solvent and then formed as a coating film. That is, a photosensitive material is applicable to the present invention so long as it has an appropriate organic solvent that would never cause any component of the material to be irreversibly decomposed, associated, or polymerized when being dissolved or dispersed.

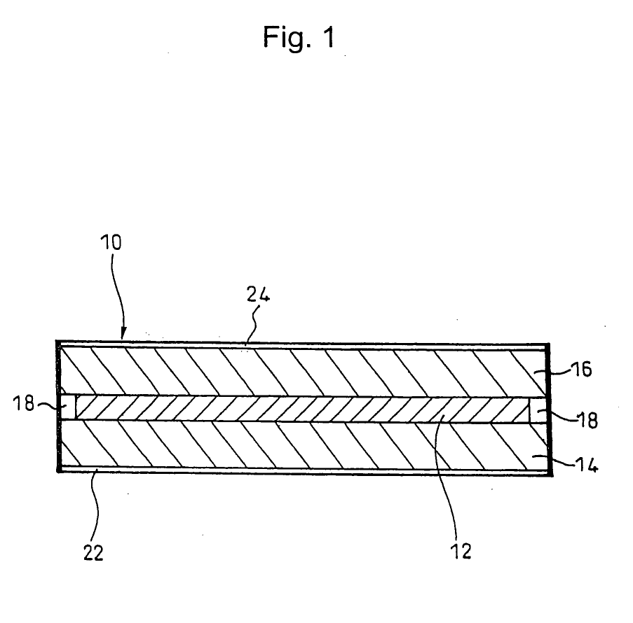

More specifically, as shown in FIG. 1, an optical recording medium 10 according to the most preferred embodiment is a transmission hologram recording medium in which an information recording layer (hologram recording material layer) 12 and a spacer 18 are sandwiched between two support substrates or transparent substrates 14 and 16 made of glass or resin. The lower side of the transparent substrate 14 in FIG. 1 and the upper side of the transparent substrate 16 in FIG. 1 have antireflective coatings 22 and 24, respectively.

The transparent substrates 14 and 16 hold the information recording layer 12 and allows light to pass therethrough. The spacer 18 is designed to provide a spacing between the transparent substrates 14 and 16 for the information recording layer 12. A light shield material 20 is designed to prevent external light through the sides of the optical recording medium 10. The information recording layer 12 is obtained, for example, by applying a hologram recording material solution to the transparent substrates 14 and/or 16, where the solution is formed by allowing a mixture of a sol solution containing an organic metal matrix material with a photopolymerizable compound to complete hydrolysis and a condensation reaction.

Note that if the information recording layer 12 can be supported only with the transparent substrate 14, then the transparent substrate 16 is not necessarily required.

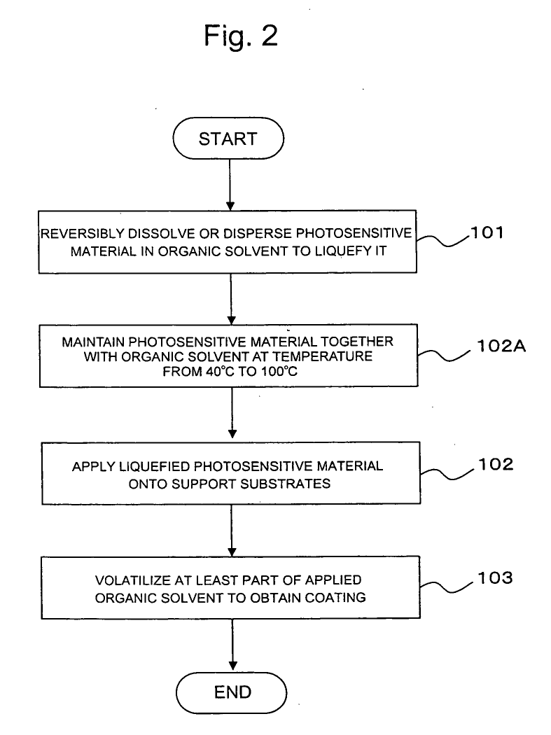

As shown in FIG. 2, a method for manufacturing an optical recording medium according to the best mode includes the steps of: allowing a photosensitive material to be reversibly dissolved or dispersed in an organic solvent and thereby liquefied (Step 101); applying the liquefied photosensitive material onto a support substrate or the transparent substrates 14 and/or 16 (Step 102); and allowing at least part of the contained organic solvent to be volatilized to obtain an information recording layer having the shape of a coating (Step 103).

In and prior to Step 102 or the step of applying the liquefied photosensitive material, the photosensitive material together with the organic solvent may be maintained, as required, at a temperature of from 40° C. to 100° C. (Step 102A)

More specifically, the aforementioned hologram recording material solution is applied onto the surface of the transparent substrates 14 and/or 16 and then dried and annealed to obtain the information recording layer 12. In more detail, the spacer 18 of a predetermined thickness is placed on the surface of the transparent substrates 14 and 16. The resulting hologram recording material solution is then applied thereto, dried for one hour at room temperatures, and subsequently dried again for 24 hours at 40° C. Then, the solvent is volatilized. Furthermore, it is heated for 48 hours under a reduced pressure of 100 hPa at 80° C. The solvent is completely volatilized in this drying step, and thus the information recording layer 12 of a dry film thickness of 450 μm is obtained which has an organic metal compound and a photopolymerizable compound evenly dispersed.

The optical recording medium 10 is made as follows. The surface of the information recording layer 12 formed on the transparent substrate 14 is coated with the transparent substrate 16. At this time, the coating should be done slowly with care so as not to trap bubbles in the interface between the transparent substrate 16 and the information recording layer 12. Alternatively, to prevent the trapping of bubbles, the coating may also be made in an atmosphere of reduced pressure. In this manner, the optical recording medium (hologram recording medium) 10 is obtained which has the information recording layer 12 sandwiched between the two transparent substrates 14 and 16.

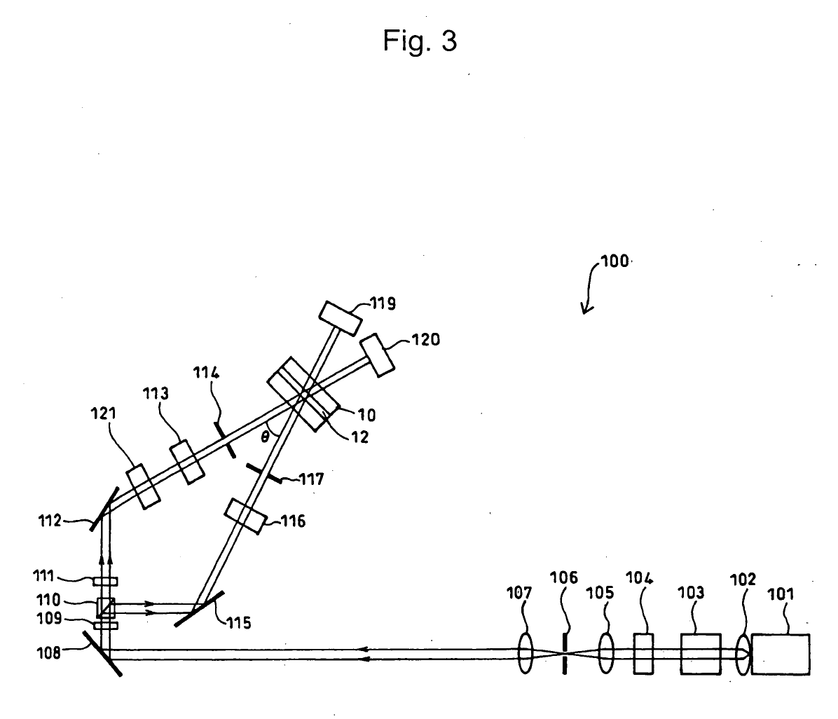

With reference to FIG. 3, a description will now be given of a hologram recording optical system 100 for performing hologram recording/reproduction on the optical recording medium 10.

In the hologram recording optical system 100, a single-mode lasing semiconductor laser (405 nm in wavelength) is used as a light source 101 to emit a laser beam. The laser beam emitted from the light source 101 passes through a beam shaper 102, an optical isolator 103, a shutter 104, a convex lens 105, a pin hole 106, and another convex lens 107, so that the beam is spatially filtered and collimated, thereby providing a laser beam having an expanded beam diameter of approximately 10 mm. The expanded beam is polarized by 45° via a mirror 108 and a half-wave plate 109, and then split through a polarizing beam splitter 110 into S wave/P wave=1/1. Furthermore, the split S wave is reflected on a mirror 115 and then passes through a polarizing filter 116 and an iris diaphragm 117. The split P wave is converted to an S wave through a half-wave plate 111 and then reflected on a mirror 112 to pass through a polarizing filter 113 and an iris diaphragm 114. The two light beams are thus directed to be incident on a sample of the hologram recording medium 10 at their total incidence angle θ of 37°, so that the interference pattern of the two beams is recorded on the sample.

To record the hologram, the sample is rotated in the horizontal direction and thereby multiplexed (angle multiplexing with a sample angle of −21° to +21° at angular intervals of 0.6°) The multiplicity is set at 71. At the time of recording, the exposure was defined with the iris diaphragms 114 and 117 set at a diameter of 4 mm. Note that the aforementioned sample angle is ±0° when the sample surface is at 90° to the line (not shown) bisecting the angle θ that the two light beams form.

To allow remaining unreacted components to react after the hologram has been recorded, the sample was irradiated with a sufficient amount of light emitted from a blue LED at a wavelength of 400 nm. At this time, the exposure was provided through an acrylic diffusing plate of transmittance 80% so that the irradiation would not have coherence (this is referred to as post-cure). At the time of reproduction, a shutter 121 blocks the light passing therethrough and the iris diaphragm 117 is reduced in diameter to 1 mm to allow only one light flux to be available for irradiation. The sample is continuously rotated from −23° to +23° in the horizontal direction, and the diffraction efficiency at the respective angular positions is measured using a power meter 120. If there was no change in volume (recording contraction) and average refractive index of the recording material layer before and after recording, the horizontal diffraction peak angles at the time of recording and reproduction are coincident with each other. However, since recording contractions and changes in average refractive index occur in practice, the horizontal diffraction peak angle during reproduction is slightly shifted from the horizontal diffraction peak angle during recording. Accordingly, during reproduction, the horizontal angle was varied successively so that the diffraction efficiency was determined from the peak strength when the diffraction peak appeared. Note that a power meter 119 was not employed in this example.

### EXAMPLE 1

### (Synthesis of Organic Metal Sol Solutions)

2.48 g of tetra-n-butoxy titanium (Ti(OC₄H₉)₄, manufactured by Kojundo Chemical Laboratory Co., Ltd.) and 2.13 g of 2-ethyl-1,3-hexanediol (manufactured by Tokyo Chemical Industry Co., Ltd.) were mixed and stirred for one day and night in 1.01 mL of n-butanol in an inert gas atmosphere at room temperature.

2.07 g of dimethoxy diphenyl silane (LS-5300, manufactured by Shin-Etsu Chemical Co., Ltd.) and 0.52 g of N-(3-triethoxysilylpropyl) gluconamide (manufactured by AZmax Co., as a 5% ethanol solution) were added to a composition of Ti(OC₄H₉)₄ and 2-ethyl-1,3-hexanediol (=1/2 in mole ratio), thereby preparing a metal alkoxide solution.

A solution of Ti/Si=8/10 (mole ratio), 0.15 mL of pure water, 0.07 mL of 2N hydrochloric acid, and 1.0 mL of ethanol was dropped into the aforementioned metal alkoxide solution at room temperature while being stirred. After that, the resulting solution was heated at 80° C. for 24 hours while being stirred, for hydrolysis reaction and condensation reaction. In this manner, the organic metal sol solution was prepared.

### (Photopolymerizable Compound)

A mixture containing a photopolymerizable compound was prepared by adding 3 weight parts of Irgacure 907 (manufactured by Ciba Specialty Chemicals Co.) as a photopolymerization initiator and 0.2 weight parts of thioxanthene-9-one (manufactured by Sigma-Aldrich Japan K.K.) as a photosensitizer to photopolymerizable compounds, i.e., 80 weight parts of polyethylene glycol diacrylate (Aronix M-245 manufactured by Toagosei Co., Ltd.) and 20 weight parts of polypropylene glycol acrylate (BLEMMER AP-550 manufactured by NOF Corporation).

### (Hologram Recording Material)

The organic metal sol solution and the photopolymerizable compound were mixed at room temperatures so that the organic metal sol (as a nonvolatile content) was contained in 90 weight parts and the photopolymerizable compound 10 weight parts. Thus, a hologram recording material composition solution was prepared. The resulting hologram recording material composition solution was applied onto a glass substrate (support substrate), as will be described below, and the solvent was evaporated, thereby providing a recording medium sample.

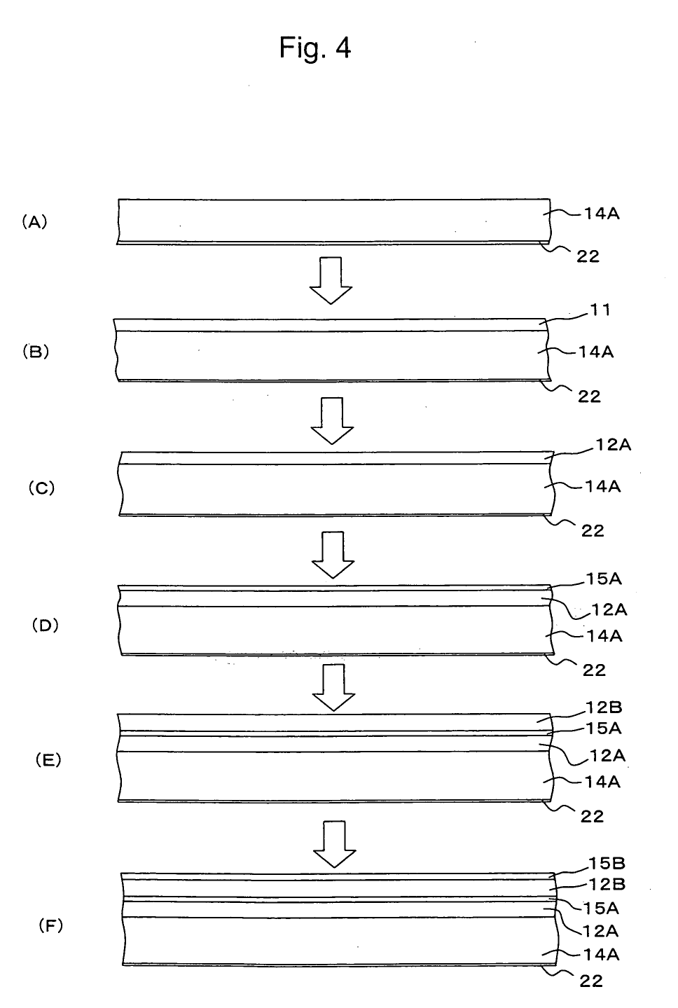

The manufacturing process of the hologram recording medium will now be described with reference to FIG. 4 (cross-sectional view) which schematically shows it. As shown in FIG. 4A, a glass substrate 14A having a diameter of 12 cm, an inner diameter of 15 mm, and a thickness of 1 mm was prepared, which had an antireflective coating 22 provided on one side thereof. Then, as shown in FIG. 4B, the resulting hologram recording material composition solution was applied by spin coating onto another side of the glass substrate 14A, on which no antireflective coating 15A was provided. It was then dried for 6 hours at 80° C. under a pressure of 100 hPa.

As a result, as shown in FIG. 4C, a smooth hologram recording material layer 12A with the organic metal sol and the photopolymerizable compound uniformly dispersed was obtained in a thickness of 60 μm.

As shown in FIG. 4D, a polycarbonate film (manufactured by TEIJIN Chemicals Ltd., 67 μm in thickness) 15A formed in the same shape as the glass substrate 14A was gently placed on and brought into intimate contact with the hologram recording material layer 12A. The polycarbonate film 15A was spin-coated with the aforementioned hologram recording material component solution in the same manner as described above and then dried for 6 hours at 80° C. under a pressure of 100 hPa. As shown in FIG. 4E, the resulting hologram recording material layer 12B had a dry film thickness of 60 μm. As shown in FIG. 4F, the same polycarbonate film 15B as above was gently placed on and brought into intimate contact with that surface.

In this manner, a hologram recording medium sample (the optical recording medium 10) was obtained which had the hologram recording material layers 12A and 12B, 60 μm in thickness, stacked in layers with the polycarbonate film 15A interposed therebetween. Hereinafter, the hologram recording material layer 12A deposited on the glass substrate 14A will be referred to as the first layer, while the hologram recording material layer 12B deposited on the polycarbonate film 15A as the second layer.

### (Evaluation of Characteristics)

The resulting hologram recording medium sample was evaluated in terms of its properties using the hologram recording optical system 100 shown in FIG. 3. For convenience, the horizontal direction is defined as the direction of the drawing surface of FIG. 3. In FIG. 3, the hologram recording medium sample is set so that the hologram recording material layer is perpendicular to the horizontal direction.

In the hologram recording optical system 100 of FIG. 3, a single-mode lasing semiconductor laser (405 nm in wavelength) was used as the light source 101 to emit a laser beam. The laser beam emitted from the light source 101 passed through the beam shaper 102, the optical isolator 103, the shutter 104, the convex lens 105, the pin hole 106, and the convex lens 107, so that the beam was spatially filtered and collimated, thereby providing a laser beam having an expanded beam diameter of approximately 10 mm. The expanded beam was polarized by 45° via the mirror 108 and the half-wave plate 109, and split using the polarizing beam splitter into an S wave/P wave=1/1. The split S wave was reflected on the mirror 115 and then passed through the polarizing filter 116 and the iris diaphragm 117. On the other hand, the split P wave was converted to an S wave through the half-wave plate 111 and then reflected on the mirror 112 to pass through the polarizing filter 113 and the iris diaphragm 114. The two light beams were thus directed to be incident on the hologram recording medium sample at their total incidence angle θ of 43°, so that the interference pattern of the two beams was recorded.

In the hologram recording optical system 100 of FIG. 3, the sample holder was designed so as to be capable of adjusting the position of the direction of the line bisecting the angle θ formed by the two light beams (in the direction of the normal to the sample). First, the holder position was adjusted so that the two light beams overlapped at the position of the first layer of the recording material layer of the sample, and then the interference pattern was recorded in the first layer.

To record the hologram, the sample was rotated in the horizontal direction and thereby multiplexed (angle multiplexing with a sample angle of −21° to +21° at angular intervals of 0.6°) The multiplicity was set at 71. At the time of recording, the exposure was defined with the iris diaphragm set at a diameter of 4 mm. Note that the aforementioned sample angle was +0° when the sample surface was at 90° to the line bisecting the angle θ that the two light beams formed.

In this manner, after the interference pattern was recorded in the first layer by angle multiplexing, the recorded interference pattern was reproduced. At the time of reproduction, the shutter blocked the light otherwise passing therethrough and the iris diaphragm was reduced in diameter to 1 mm to allow only one light flux to be available for irradiation. The sample was continuously rotated from −23° to +23° in the horizontal direction, and the diffraction efficiency at the respective angular positions was measured using a power meter. If there was no change in volume (recording contraction) and average refractive index of the recording material layer before and after recording, the horizontal diffraction peak angles at the time of recording and reproduction would be coincident with each other.

However, since recording contractions and changes in average refractive index occur in practice, the horizontal diffraction peak angle during reproduction is slightly shifted from the horizontal diffraction peak angle during recording. Accordingly, during reproduction, the horizontal angle was varied successively, so that the diffraction efficiency was determined from the peak strength when the diffraction peak appeared.

At this time, a dynamic range M/# (the total sum of the square roots of diffraction efficiencies at each diffraction peak) was 24.5 (a converted value assuming the hologram recording material layer had a thickness of 1 mm). Furthermore, the average recording sensitivity until the aforementioned M/# reached 80% of its value was found to be 0.60 cm/mJ.

Then, in the hologram recording optical system 100 of FIG. 3, the position of the sample holder was adjusted so that the two light beams interfered with each other on the second layer. Then, in the same manner as with the first layer, the interference pattern was recorded by angle multiplexing.

At this time, the dynamic range M/# was found to be 24.8. Furthermore, the average recording sensitivity was observed as being 0.61 cm/mJ. That is, it was shown that the first layer and the second layer, or the recording material layers which had been made of the same recording material composition solution, were formed as the films that had almost the same recording characteristics.

Furthermore, on the first layer and the second layer, recording and reproduction were performed at three points thereof in the same recording condition. As shown in Table 1, it was then shown that almost the same recording characteristics were obtained at any of the points.

TABLE 1

| | | First | Second |
|---|---|---|---|
| | | layer | layer |
| First | M/# (Converted for 1 mm in thickness) | 24.5 | 24.8 |
| point | Sensitivity (cm/mJ) | 0.60 | 0.61 |
| Second | M/# (Converted for 1 mm in thickness) | 24.1 | 24.6 |
| point | Sensitivity (cm/mJ) | 0.60 | 0.61 |
| Third | M/# (Converted for 1 mm in thickness) | 24.7 | 24.2 |
| point | Sensitivity (cm/mJ) | 0.61 | 0.60 |

### COMPARATIVE EXAMPLE

With reference to Example 1 in WO 2005/078532, a photopolymerizable monomer was dispersed in a matrix cross-linked three-dimensionally by chemical bonding to prepare a recording material layer. The raw material composition of the recording material is as shown in Table 2 below.

TABLE 2

| | Weight |
|---|---|
| Raw material | parts |
| (a) Epoxy diacrylate of glycerin diglycidyl ether | 20 |
| (EPOLIGHT 80 MFA by KYOEISHA CHEMICAL) | |
| (b) Modified glycerol propylene oxide (molecular | 80 |
| weight 400) | |
| (G-400 by ADEKA) | |
| (c) Hexamethylene diisocyanate | 62 |
| (Duranate HDI by Asahi Kasei) | |
| (d) Di-n-butyltin dilaurate | 0.02 |
| (DBTL by ADEKA) | |
| (e) EO modified tribromophenyl acrylate | 10 |
| (New Frontier BR-31 by Dai-ichi Kogyo Seiyaku) | |
| (f) Photopolymerization initiator | 3.0 |
| (Irgacure 907 by Ciba Specialty Chemicals) | |
| (g) Photosensitizer | 0.02 |
| (2.4-diethyl-9H-thioxanthene-9-one) | |
| (h) N,N-dimethylbenzylamine | 3.9 |

The aforementioned raw materials were stirred for 2 hours in an inactive gas atmosphere to be evenly dissolved. This composition was applied by spin coating to the first glass substrate in the same manner as in the example 1. Then, likewise, the aforementioned composition was also applied by spin coating to the second glass substrate of the same shape. Note that the application by spin coating to the second glass substrate was carried out when 1 hour elapsed after the first glass substrate was spin coated. The glass substrates to which the hologram recording material composition was applied in this manner were placed opposite and affixed to each other via a polycarbonate film 67 μm in thickness (manufactured by TEIJIN Chemicals Ltd.) under a reduced atmospheric pressure. The opposing first and second glass substrates were held at room temperature for one day and night so that their spacing was 267 μm, i.e., the total thickness of the recording layer excluding that of the polycarbonate film was 200 μm.

In this manner, the hologram recording medium sample was obtained in which the hologram recording material layers were stacked in layers with the polycarbonate film interposed therebetween. Note that the recording layer formed on the glass substrate 1 is referred to as the first layer, and the recording layer formed on the glass substrate 2 as the second layer.

In the same manner as in the example 1, the two-light-beam interference pattern angle-multiplexed recording was performed on the resulting hologram recording medium sample using a plane wave. As with the example 1, recording was carried out at three-positions of each of the first and second recording layers for comparison of their characteristics. The comparison results are summarized in Table 3.

TABLE 3

| | | First | Second |
|---|---|---|---|
| | | layer | layer |
| First | M/# (Converted for 1 mm in thickness) | 18.8 | 11.9 |
| point | Sensitivity (cm/mJ) | 0.15 | 0.09 |
| Second | M/# (Converted for 1 mm in thickness) | 14.2 | 16.3 |
| point | Sensitivity (cm/mJ) | 0.09 | 0.12 |
| Third | M/# (Converted for 1 mm in thickness) | 16.4 | 10.5 |
| point | Sensitivity (cm/mJ) | 0.10 | 0.04 |

As can be seen clearly from Table 3, the recording characteristics were found to vary a great deal. This is partly because the cross-linking reaction takes places after the multilayer structure is formed and thus the stress due to polymerization shrinkage has remained unevenly inside the recording layers. Furthermore, the first layer and the second layer do not have the same isocyanate/epoxy reactivity at the time of spin coating because different periods of time elapsed after the respective compositions were prepared. Accordingly, even when the layers were formed under the same spin coating conditions, they would have slightly different film thicknesses. This can also be thought as a factor of variations in recording characteristics.

Note that the embodiment provides an information recording layer formed in one layer, whereas the aforementioned example provides the information recording layers 12A and 12B formed in two layers. However, without limiting thereto, the present invention is also applicable to information recording layers formed in three or more layers. In this case, those information recording layers are separated from each other by an isolation layer. The isolation layer can be made insensitive to light of recording/reproduction wavelengths and provided with a lower extinction coefficient than that of the information recording layers. The inventors confirmed that this made it possible to record information with accuracy on up to 20 layers.

The aforementioned example was realized by applying the present invention to a hologram recording medium; however, without limited thereto, the present invention may also be applied to other types of optical recording media. For example, those media may include optical devices other than the hologram recording media, such as hologram sheets for design or counterfeit-resistance purposes, or various kinds of optical devices such as hologram screens for displaying stereographic images. The coating method according to the present invention can be employed to successively coat flexible large-area substrate materials with ease, thus facilitating high volume production of those optical devices at low costs. Furthermore, since the storage stability required of these optical devices is almost the same as that of the aforementioned recording media, the photosensitive material like the hologram recording material of the example can be preferably employed for these optical devices.

Note that specific examples of hologram sheets for design purposes can be found in Japanese Patent Application Laid-Open No. Hei 11-249536 and No. 2005-309452. Furthermore, a specific example of hologram screens for displaying stereographic images may be found in WO 99/5070.2.

The present invention provides an optical recording medium which has an information recording layer formed of photopolymer for hologram recording material. The optical recording medium has stable recording characteristics because of its matrix rigidity that is assured not by covalent bonding but by physical, reversible, three-dimensional, cross-linking. The medium can also have the information recording layer formed by general-purpose deposition methods such as by spin coating or screen printing.

What is claimed is:

1. An optical recording medium comprising:
a support substrate; and
an information recording layer supported on the support substrate and made of a photosensitive material capable of recording a hologram when being irradiated with light, wherein the information recording layer has a shape of a coating which is formed by applying the photosensitive material that is reversibly dissolved or dispersed in an organic solvent onto the support substrate.

2. The optical recording medium according to claim 1, wherein the information recording layer is stacked in multiple layers via an isolation layer, and the isolation layer is insensitive to light of a recording/reproduction wavelength and has an extinction coefficient lower than that of the information recording layer.

3. A method for manufacturing an optical recording medium, the optical recording medium having a support substrate and an information recording layer supported on the support substrate and made of a photosensitive material capable of recording a hologram when being irradiated with light, the method comprising: applying the photosensitive material that is reversibly dissolved or dispersed in an organic solvent onto the support substrate; and volatilizing at least part of the organic solvent to form the information recording layer having a shape of a coating.

4. The method for manufacturing an optical recording medium according to claim 3, wherein the step of applying the photosensitive material is performed while maintaining the photosensitive material together with the organic solvent at a temperature from 40° C. to 100° C.
